(19) United States
(12) Patent Application Publication
(10) Pub. No.: US 2026/0246248 A1
(43) Pub. Date: Aug. 20, 2026

(54) ENHANCED HEAT EXCHANGE MECHANISM FOR WALL PLATE DEVICES

(71) Applicant: KRAMER ELECTRONICS LTD., Airport City (IL)

(72) Inventors: Shlomi EFRATI, Mevasseret Zion (IL); Gleb DANILENKO, Holon (IL); Rani BEN YELID, Zoran - Kadima (IL); Naftali BEN PAZ, Rehovot (IL)

(21) Appl. No.: 18/878,961

(22) PCT Filed: Aug. 8, 2023
(86) PCT No.: PCT/IL2023/050823

§ 371 Date: Dec. 26, 2024

(30) Foreign Application Priority Data
Aug. 9, 2022 (US) 63396238

(51) Int. Cl. H02G 3/03; H02G 3/08; H02G 3/12; H05K 7/20

(52) U.S. Cl. CPC H02G 3/03; H02G 3/081; H02G 3/121; H05K 7/20145

(57) ABSTRACT

The present invention relates to a wall plate device embeddable within a wall or other fixed medium, comprising: a housing comprising a rear cover optionally in the form of a box and a front panel; a suction opening placed at the frontage of said device; an exhaust opening placed at the frontage of said device; at least one PCB placed within said rear cover with input and output connectors; at least one electronic component connected to said PCB; a ventilation device configured to propel an air flow from said suction opening and to said exhaust opening, part of which passes adjacent to said electronic component.

### FIELD OF THE INVENTION

The present invention relates to the field of heat control. More particularly, the present invention relates to temperature control for electronic devices.

### BACKGROUND OF THE INVENTION

Indoor infrastructure is usually deployed within the walls of buildings, on the floor, on the ceiling, or through furniture. It includes, in addition to water and electricity, also communications. Technological developments in communications have pushed the boundaries toward higher speed for achieving both high throughput and bandwidth. These demands are the primary enabler for smart homes, conference halls, stadium event streaming and more.

High-speed communication for transmitting audio and video signals is also becoming challenging in terms of heat dissipation generated in the electronic components. The terminal units embedded in a fixed medium (such as walls or tables), including these circuits, are packed in common standard housing boxes, from the field of electrical infrastructure.

FIG. 1 shows a standard wall plate device (1 Gang dimensions). The front side of the wall plate device has an input terminal for receiving an HDMI connection. The rear side of the wall plate device has an output terminal connectable to a built-in cable for network audio/video, power and control. The front side of the wall plate device may be connected to terminal devices, audio/video, sources/sinks, or other computer-based devices.

FIG. 2 shows various components of a wall plate device 1 in exploded view. An electrical outlet communication Box 8 embeddable within a wall is shown. The electrical outlet communication Box 1 has a recess configured to receive an inner cover 7. The inner cover 7 is configured to receive a front Printed Circuit Board (PCB) 5 and a rear Printed Circuit Board (PCB) 6. A front panel installation frame 4 is placed in front of the front PCB 5 and a front panel cover frame 3 is placed in front of the front panel installation frame 4. A front panel cover 2 is placed in front of the front panel cover frame 3 and is secured to the wall. Insert inputs 2a and 2b are shown on the front panel cover 2 (2 Gang sized device).

FIG. 3 shows a side view of the front panel cover 2 and the inner cover 7 of the wall plate device 1, when the above elements are assembled for use.

FIG. 4 shows a wall plate device 1 mounted and embedded within a wall. The wall installation medium 11 which the wall plate device 1 is embedded within is shown. The inner cover 7 is shown within the electrical outlet communication Box 8, and the front panel cover 2 is shown in the frontage.

A combination of a given volume that is supposed to contain densely populated electronic components which heat up during function may cause malfunction and damage to the device. For example, an electronic component with a high operating frequency creates physical challenges for heat dissipation, whose conduction principle does not allow for efficient heat management. This example is especially relevant, when there is a need for high-speed communication for transmitting audio and video signals, or in cases when the use is with an efficiency that is not 100%. In FIG. 2, an electronic device load (that processes said signals) is connected to a respective rear PCB 6 and contributes to accumulating heat. The accumulated heat could cause malfunction and damage to the wall plate device 1 components.

U.S. Pat. Nos. 10,433,455, 7,726,982, JPH09130073A, and JP2000101273A relate to cooling apparatuses. U.S. Pat. No. 10,433,455 relates to a wiring device that includes a housing that encloses a line voltage port and/or a low voltage port for providing power to at least one removable/rechargeable load. The housing has an intake opening and an exhaust opening for drawing cooling air into the housing and for exhausting heated air. A fan is mounted within the housing and operates to move the air through the housing. However, if the device of U.S. Pat. No. 10,433,455 is fully embedded within a wall it is not clear how the air flow is carried out and to what extent it could provide efficient cooling. In this device, the air input opening is placed at its rear side within the wall, thereby preventing proper air flow. Furthermore, there is no clear air flow path described therein, which is the key to an effective cooling.

It is therefore an object of the present invention to provide a method and means for high-speed electronics within a wall plate device and for an efficient cooling of components thereof.

It is a further object of the present invention to provide a method and means for cooling an electronic device which processes high-speed audio/video signals within a wall plate device, while transmitting high-speed signals.

Other objects and advantages of the present invention will become apparent as the description proceeds.

### SUMMARY OF THE INVENTION

The present invention relates to a wall plate device providing cooling means for cooling its internal components. The wall plate device comprises two front openings and is configured to pass an air flow stream within its interior (from one of the openings, via its interior (e.g. a duct pathway), to the other opening and out of the device). A ventilation device is placed within the wall plate device interior and is configured to propel the air flow stream. As an electronic component frequently causes the heating within the wall plate device, a heat sink may be attached thereto and the cooling air stream may pass through/aside the heat sink, thereby contributing to cooling the device. The air stream magnitude may be varied in accordance with the temperature within the device. The wall plate device preferably comprises a control unit coupled to the ventilation device and to a sensor, such that the activation magnitude of the ventilation device is according to the sensor readings.

The present invention relates to a wall plate device embeddable within a wall or other fixed medium, comprising:
a housing comprising a rear cover, optionally in the form of a box and a front panel;
a suction opening placed at the frontage of said device;
an exhaust opening placed at the frontage of said device;
at least one PCB placed within said rear cover with input and output connectors;
at least one electronic component connected to said PCB;
a ventilation device configured to propel an air flow from said suction opening and to said exhaust opening, part of which passes adjacent to said electronic component.

Preferably, the ventilation device and electronic component are placed within a duct; and wherein the air flow passes along said duct.

Preferably, the ventilation device is placed between the electronic component and the suction opening along the duct.

Preferably, the ventilation device is a fan.

Preferably, the suction opening and the exhaust opening are openings in the front panel.

Preferably, the wall plate device further comprises a plurality of fin surfaces attached to the front panel;
wherein a plurality of said fin surfaces are placed near the suction opening; and
wherein a plurality of said fin surfaces are placed near the exhaust opening.

Preferably, the wall plate device further comprises a vertical entrance channel and a vertical exit channel;
wherein said vertical entrance channel is coupled at one end to the suction opening and at the other end to the interior of the duct; and
wherein said vertical exit channel is coupled at one end to the exhaust opening and at the other end to the interior of the duct.

Preferably, said device further comprises a control unit comprising a processor, and a sensor;
wherein the control unit is coupled to said sensor and coupled to said ventilation device.

Preferably, the sensor is a temperature sensor.

Preferably, the ventilation device is a blower configured to receive an air flow from an input from one direction and emit an air flow from an output at another direction;
wherein said output faces the exhaust opening.

Preferably, the ventilation device is a blower configured to receive an air flow from an input from one direction and emit an air flow from an output at another direction;
wherein said output faces one end of the exit channel.

Preferably, the device comprises a front PCB and a rear PCB placed within said rear cover, each having input and output connectors;
wherein the ventilation device and electronic component are placed between the front PCB and rear PCB.

Preferably, the front PCB comprises an audio or video input connector; and
wherein the rear PCB is connected to said front PCB.

Preferably, the front PCB comprises an audio or video input connector; and
wherein the rear PCB comprises an audio or video output connector.

Preferably, the wall plate device further comprises a heat sink that engages the electronic component;
wherein part of the air flow passes adjacent to said heat sink.

The present invention relates to a wall plate device embeddable within a wall or other fixed medium, comprising:
a housing comprising a rear cover, optionally in the form of a box and a front panel;
an upper opening placed at the frontage of said device;
a bottom opening placed at the frontage of said device;
a middle opening placed at the frontage of said device and between said upper opening and bottom opening;
at least one PCB placed within said rear cover with input and output connectors;
at least one electronic component connected to said PCB;
a heat sink engaging said electronic component;
a fan facing the heat sink and configured to blow air directly on said heat sink;
wherein said fan is configured to propel:
a. a first air flow via said middle opening into said device, and on to the heat sink;
b. a second air flow from said heat sink to the upper opening;
c. a third air flow from said heat sink to the bottom opening.

The present invention relates to a method for removing heat from a wall plate device, comprising passing an air flow through a duct in said wall plate device comprising:
passing an air flow through a suction opening at the frontage of said wall plate device to the interior of said wall plate device;
directing said air flow such that a portion thereof passes near an electronic component;
directing said air flow through an exhaust opening at the frontage of said wall plate device out of said wall plate device.

Preferably, providing the wall plate device comprises a ventilation device, a temperature sensor and a control unit coupled to said ventilation device and to said temperature sensor;
the method further comprises:
determining a temperature from said temperature sensor;
setting the ventilation device to an activation mode depending on the temperature determined.

According to embodiments of the present invention, the present invention ventilation device is a Solid State Cooling Device (SSCD). The present invention wall plate device comprises an SSCD that has an internal mechanism that manipulates an air flow from a suction opening to an exhaust opening. The air travels within a duct via the SSCD. The air flow is suctioned (in negative pressure) through the suction opening, passes via the SSCD device (which propels the air flow) and out thereof, and directed out of the wall plate device through the exhaust opening of the wall plate device. The air traveling within the SSCD travels along the inner side of a surface where the outer side of the surface engages an electric component that heats up. The air flow introduces cool air from the external environment that passes along the inner side of the engaging surface, thereby cooling the engaging surface. The cooled engaging surface reduces the electric component heat stress which it engages, thereby contributing to a better function of the electric component, longer function time and longer life span. This also contributes to enable the electric component to work with higher heat loads and at higher frequencies.

The present invention relates to a wall plate device embeddable within a wall or other fixed medium, comprising:
a housing comprising a rear cover, optionally in the form of a box and a front panel;
a suction opening placed at the frontage of said device;
an exhaust opening placed at the frontage of said device;
at least one PCB placed within said rear cover with input and output connectors;
at least one electronic component connected to said PCB;
an SSCD placed adjacent to said electronic component;
wherein said SSCD is configured to propel an air flow from said suction opening via said SSCD and out through said exhaust opening.

Preferably, the SSCD comprises inlet vents and an outlet opening.

Preferably, the device further comprises a vertical entrance channel and a vertical exit channel;
wherein said vertical entrance channel is coupled at one end to the suction opening and sealably coupled at the other end to an inlet duct;
wherein said vertical exit channel is coupled at one end to the exhaust opening and sealably coupled at the other end to an outlet duct;
wherein the inlet duct is sealably coupled to the SSCD such that air is configured to pass from the inlet duct into the SSCD interior only through the inlet vents; and
wherein the outlet duct is sealably coupled to the SSCD such that air is configured to pass from the SSCD interior to the outlet duct only through the SSCD outlet opening.

Preferably, the SSCD outlet opening is in the form of a spout.

Preferably, the device further comprises control unit comprising a processor, and a sensor;
wherein the control unit is coupled to said sensor and coupled to said SSCD.

Preferably, the sensor is a temperature sensor.

Preferably, the system comprises a front PCB and a rear PCB placed within said rear cover, each having input and output connectors;
wherein the electronic component is attached to the rear side of the rear PCB and the SSCD is placed adjacent to the rear side of the electronic component.

The present invention relates to a method for removing heat from a wall plate device, comprising passing an air flow through a duct in said wall plate device comprising:
passing an air flow through a suction opening at the frontage of said wall plate device to the interior of an SSCD;
directing said air flow from the SSCD interior an exhaust opening at the frontage of said wall plate device out of said wall plate device.

Preferably, the method further comprises:
providing the wall plate device comprises a temperature sensor and a control unit coupled to the SSCD and to said temperature sensor;
determining a temperature from said temperature sensor;
setting the SSCD to an activation mode depending on the temperature determined.

### BRIEF DESCRIPTION OF THE DRAWINGS

The present invention is illustrated by way of example in the accompanying drawings, in which similar references consistently indicate similar elements and in which:

FIG. 1 illustrates a standard wall plate prior art device in relation to the present invention.

FIG. 2 illustrates another standard wall plate prior art device in relation to the present invention.

FIG. 3 illustrates a side view of an assembled wall plate prior art device.

FIG. 4 illustrates a wall plate prior art device mounted within a wall.

FIG. 5 illustrates a cross-section view of an embodiment of the present invention.

FIG. 6 illustrates a cross-section view of an embodiment of the present invention.

FIG. 7 illustrates a cross-section view of an embodiment of the present invention.

FIG. 8 illustrates a cross-section view of an embodiment of the present invention.

FIG. 9 illustrates a cross-section view of an embodiment of the present invention.

FIG. 10 illustrates a block diagram of the present invention components according to an embodiment of the present invention.

FIG. 11 illustrates the 3D heat map of the inner components of the rear PCB emphasizing the electronic device temperature without the attached heatsink according to an embodiment of the present invention.

FIG. 12 illustrates a similar figure to FIG. 11 just with the heatsink attached to the electronic device, according to an embodiment of the present invention.

FIG. 13 illustrates a heat map of a front view of the front panel cover during use, according to an embodiment of the present invention.

FIG. 14 illustrates a front diagram on the front panel cover (and air flow direction and velocity) according to an embodiment of the present invention.

FIG. 15 illustrates a heat map of an inside view of the device during use, according to an embodiment of the present invention.

FIG. 16 illustrates an inside view of the device during use (and air flow direction and velocity) according to an embodiment of the present invention.

FIG. 17 illustrates a heat map of an inside side view of the device during use, according to an embodiment of the present invention.

FIG. 18 illustrates an inside side view of the device during use (and air flow direction and velocity) according to an embodiment of the present invention.

FIG. 19 illustrates an SSCD according to an embodiment of the present invention.

FIG. 20 illustrates a cross-section of an SSCD according to an embodiment of the present invention.

FIG. 21 illustrates a cross-section view of an embodiment of the present invention.

FIG. 22 illustrates an exploded-view of an embodiment of the present invention.

FIG. 23 illustrates a perspective back view of an embodiment of the present invention.

FIG. 24 illustrates a perspective front view of an embodiment of the present invention.

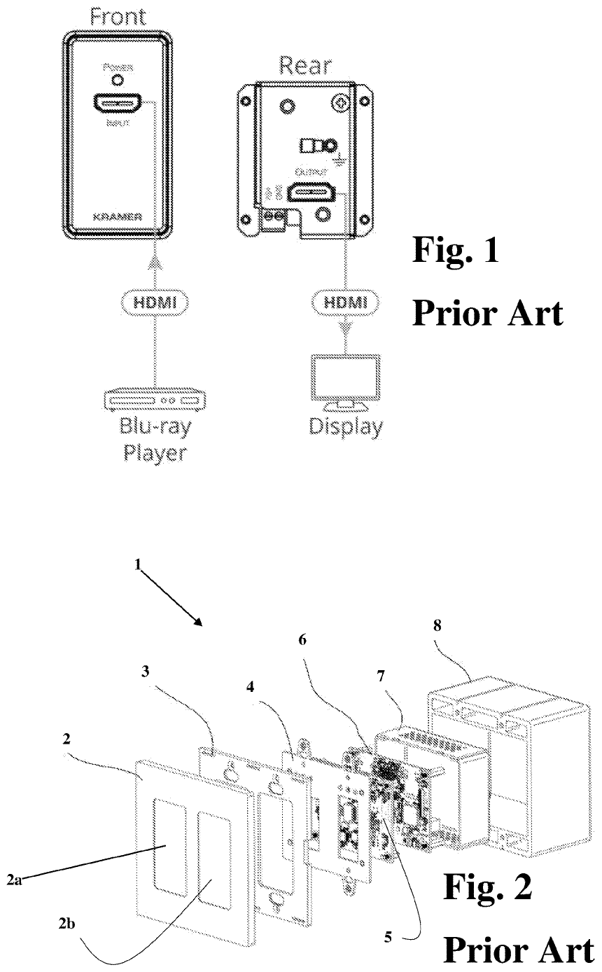

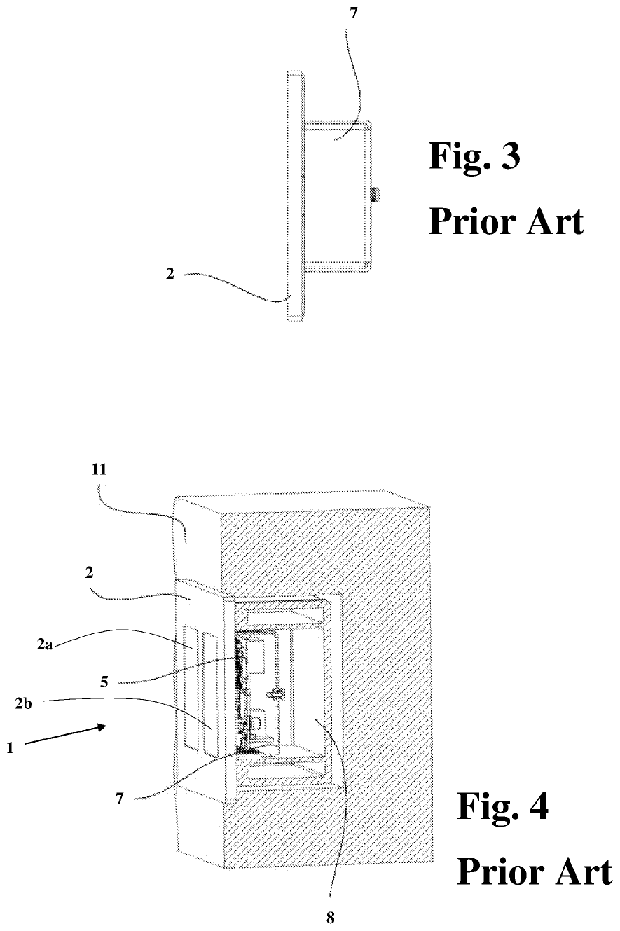

### DETAILED DESCRIPTION OF THE INVENTION

The present invention relates to system comprising a wall plate device configured to process audio/video signals. The wall plate as described herein may comprise all of the elements as described hereinabove in relation to wall plate device 1, along with additional features as described herein. The present invention wall plate device comprises a front top opening and a front bottom opening, both of which are coupled to the air external to the wall plate device frontage (i.e. the air within the room beyond and in front of the front panel cover (more forward than the front panel cover)), herein also described as an external environment. One of the front openings is used as a suction intake opening and the other opening as an exhaust opening. According to one embodiment, the wall plate device is configured to receive audio/video input/output connectors that deliver the audio/video signals.

The interior of the wall plate device inner cover comprises a chamber comprising a ventilation device configured to cause an air flow from the suction opening to the exhaust opening. The ventilation device causes the air sucked in from the suction opening to flow along a duct path within the chamber and cool off the electronic device which processes the audio/video signals. Accordingly, a duct is formed where the cool external air enters the suction opening, thereby an air stream travels along the duct (at some point partially via the ventilation device) and on the processing electronic device, cooling it off. The cooling of the electronic device enables it to function longer and at higher frequencies, thus enabling high-speed transmissions and an improved system's function. The ventilation device may be, for example, an Axial Fan, a Tubeaxial Fan, a Vaneaxial Fan, blowers or any other relevant fan form factor.

The system may comprise a heat sink that engages or is near the electronic processing device which assists in cooling the electronic processing device. The cool air entering the system replaces the hot air generated inside the device due to its electrical operation. This contributes to the heat dissipation efficiency. The ventilation device is configured to propel an air flow from the suction opening via the heat sink and to the exhaust opening. The present invention cooling system is configured to cool various heated components of the wall plate device according to an embodiment of the present invention. The present invention may be particularly advantageous as it may combine a convection cooling means (e.g. ventilation device) with a conduction cooling means (e.g. heat sink).

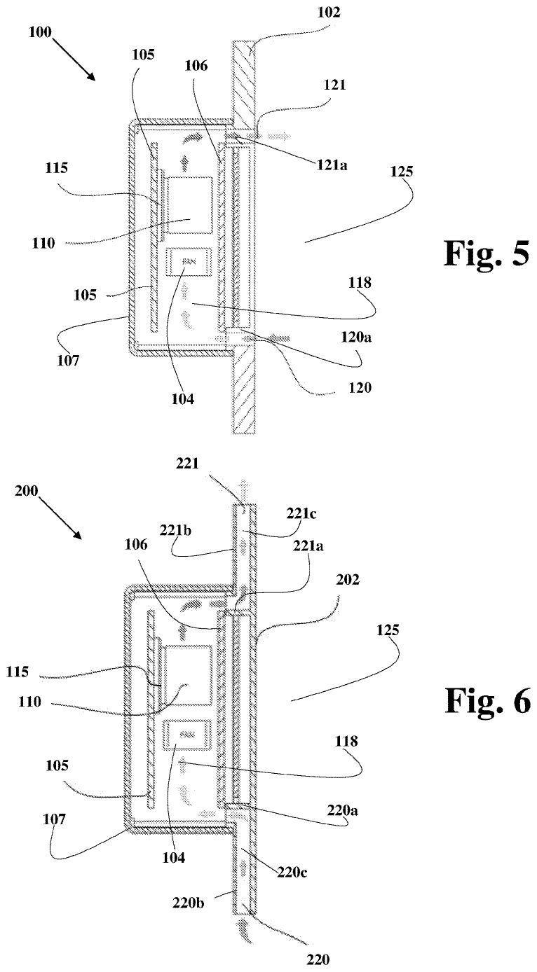

FIG. 5 shows a cross-section of a preferred embodiment of the present invention. A wall plate device 100 is shown embeddable within a wall. The wall plate device 100 comprises an inner cover 107 preferably in the form of a box. The inner cover 107 houses a vertical front PCB 106 and a vertical rear PCB 105. It should be noted that the embodiment of FIG. 5 shows two PCBS, however, other embodiments may be carried out with one PCB, mutatis mutandis. When a connector (e.g. an audio/video connector) is inserted through an insert input, it connects to the front PCB 106 (the input port not shown). The front PCB 106 is connected via a Board-to-Board (BTB) connector to the rear PCB 105. One or more electronic components, e.g. a (typically high power) electronic device 115 is/are connected to the front side of the rear PCB 105 (e.g. by being soldered thereto), and processes the high-speed input signals that pass via the connector to the front PCB 106 and thereafter (via the connector) to the rear PCB 105 and thereafter to the electronic device 115. The electronic device 115 processes the input high-speed signals and heats up during the process. The electronic device 115 (or rear PCB 105) has an output (not shown) connected to an appropriate output within the wall infrastructure at the rear side of the rear PCB 105. A front panel cover 102 is placed vertically more forward to the front PCB 106. A housing is thereby formed having a rear box structure (cover 107) and a front panel 102 (closing the front opening of the box). It should be clear that the front/forward direction herein is referred to the direction from the rear PCB 105 to the front PCB 106, towards the room interior away from the wall. The rear/backward direction herein is the opposite of the front/forward direction.

FIG. 5 shows the duct/channel path 118 formed by a bottom suction opening 120 (at the front panel cover 102), the area between the front PCB 106 and the rear PCB 105 and a top exhaust opening 121. A fan 104 is placed between the front PCB 106 and the rear PCB 105 in a direction such that it blows air upwards, in a direction perpendicularly to the front PCB 106 and the rear PCB 105 (wherein the front PCB 106 and the rear PCB 105 are substantially parallel to one another). The fan 104 is configured to cause an air flow entering from the suction opening 120, travel vertically upwards along the duct path 118 and blow air horizontally out of the exhaust opening 121. Other configurations may include other placement locations of the fan (e.g. in case there is only one PCB, e.g. at the rear side of a PCB). Part of the air flowing within the chamber within cover 107 may not necessarily flow between the PCBs but the fan 104 is placed such that a major portion of the flow does.

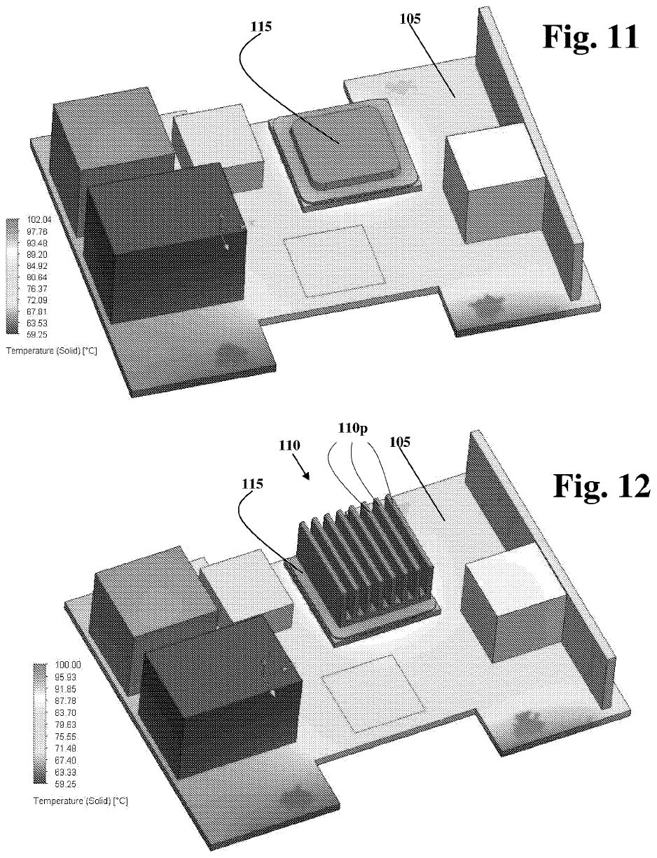

The electronic device 115 is connected (e.g. soldered) to the front side of the rear PCB 105 (other configurations may be different). A heat sink 110 is mounted on electronic device 115 (e.g. by a sticker or conductive adhesive material). The fan 104 blows air through the heat sink 110 and cools it off, thereby cooling the electronic device 115. The heat sink 110 preferably comprises a plurality of parallel ribs placed such that air blown from the fan 104 passes between the parallel ribs (shown in FIG. 11), thereby contributing to cooling it. The heat sink 110 ribs enlarge the surface area thereby enabling a better cooling. The air that passes the heat sink 110 absorbs the heat generated by the electronic device and exits the wall plate device 100 via the top exhaust opening 121.

This structure causes an air circulation that provides fresh cool air from the external environment 125 within the room that the wall plate device 100 is mounted in, and an exhaust with heated air that exits the device. The fresh cool air from the environment is preferably taken from an area distant to where the exhaust opening 121 emits the heated air, thereby not inserting heated air back into the system, improving efficiency. The air from the environment is cooler than that of within the wall plate device (which is hotter due to the electronic operation therewithin).

It should be noted that the suction opening may be at the bottom or at the top of the duct and the exhaust opening at the top or bottom of the duct respectively. The fan is positioned accordingly, mutatis mutandis. The suction and exhaust openings may be located on both sides of the wall plate device, possibly in the right-left sides of the wall plate device, with the flow elements arranged accordingly, mutatis mutandis. In some case, for most efficiency, the suction and exhaust openings are distant from one another, e.g., each being close to the cover 107 wall surface at opposite ends.

In the embodiment of FIG. 5 the openings 120 and 121 are apertures in the front panel cover 102, leading to the duct path 118. The cool air enters the suction opening 120 in a substantial horizontal direction, and the heated air exits the exhaust opening 121 in a substantial horizontal direction. According to a preferred embodiment, surface 120a is placed between the top of opening 120 and the front PCB 106 directing the flow to pass between the two PCBs 106 and 105, thereby maximizing cool air flow between the PCBs 106 and 105 towards fan 104 for the cooling process. A surface 121a is placed between the bottom of opening 121 and the front PCB 106 maximizing emission of the hot air out of the system via opening 121.

The following embodiments are similar to the embodiment of FIG. 5 comprising similar elements, unless specifically stated otherwise.

FIG. 6 shows a similar embodiment to that of FIG. 5 (and therefore the numbering of the same elements is similar) only with the suction and exhaust openings structured slightly different. In the embodiment of FIG. 6, the wall plate device 200 is preferably placed in a direction slightly more front that the embodiment of FIG. 5. The front panel cover 202 is also placed in a more forward direction. The inner cover 107 typically terminates at the wall frontage.

A vertical surface 221b (typically aligned with the wall frontage) is placed from the top of the inner cover 107 opening vertically upwards. Thus, a vertical air exit channel 221c is formed between the vertical surface 221b and the rear side of the front panel cover 202 (and preferably two side surfaces not shown). The air exit channel 221c emits the heated air from the system in a vertical direction upwards. The exhaust opening 221 (which may be round) is placed at the top of the exit channel 221c.

A vertical surface 220b (typically aligned with the wall frontage) is placed from the bottom of the inner cover 107 opening vertically downwards. Thus, a vertical air entrance channel 220c is formed between the vertical surface 220b and the rear side of the front panel cover 202 (and preferably two side surfaces not shown). The air entrance channel 220c receives the cool air from the external environment 125 (room interior) in a vertical direction upwards. The suction opening 220 (which may be round) is placed at the bottom of the air entrance channel 220c.

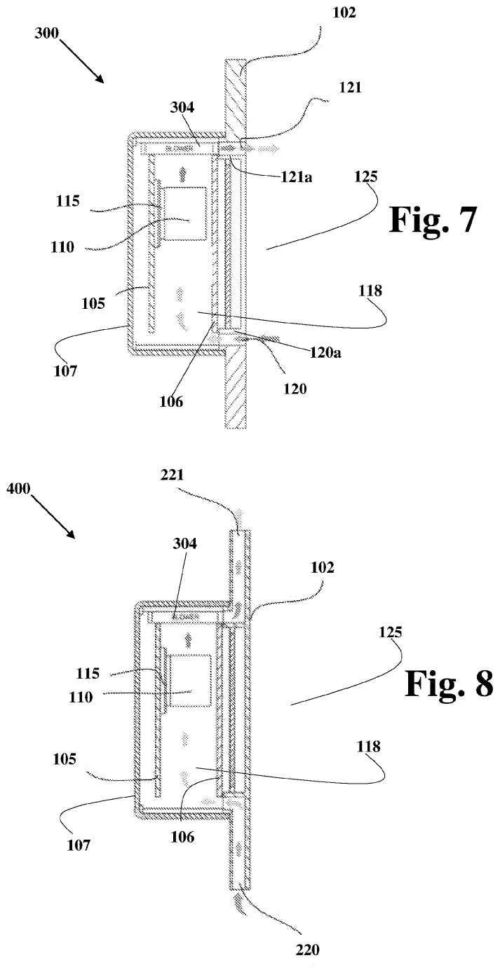

FIG. 7 shows a similar embodiment to that of FIG. 5 (and therefore the numbering of the same elements is similar) only with the use of a different ventilation device placed differently. Instead of the fan 104, the wall plate device 300 comprises a blower 304, placed horizontally at the top of the inner cover 107 interior. The blower 304 is configured to draw an air stream from beneath traveling vertically upwards and emit the air horizontally to the exhaust opening 121. This structure causes a stream of cool air to enter the suction opening 120 (in a similar manner as in the embodiment of FIG. 5) and travel vertically upwards along the duct path 118 passing the heat sink 110. The heated air that passed the heat sink 110 is sucked vertically upwards into the blower 304 from beneath and emitted horizontally to the exhaust opening 121 and out of the system.

FIG. 8 shows an embodiment of the wall plate device 400 with the blower 304 (without fan 104) placed as explained in the embodiment of FIG. 7 along with the elements 221c, 221b, 220c and 220b as explained in relation to FIG. 6, mutatis mutandis. For the sake of brevity, this embodiment will not be detailed and is clearly understood according to the above.

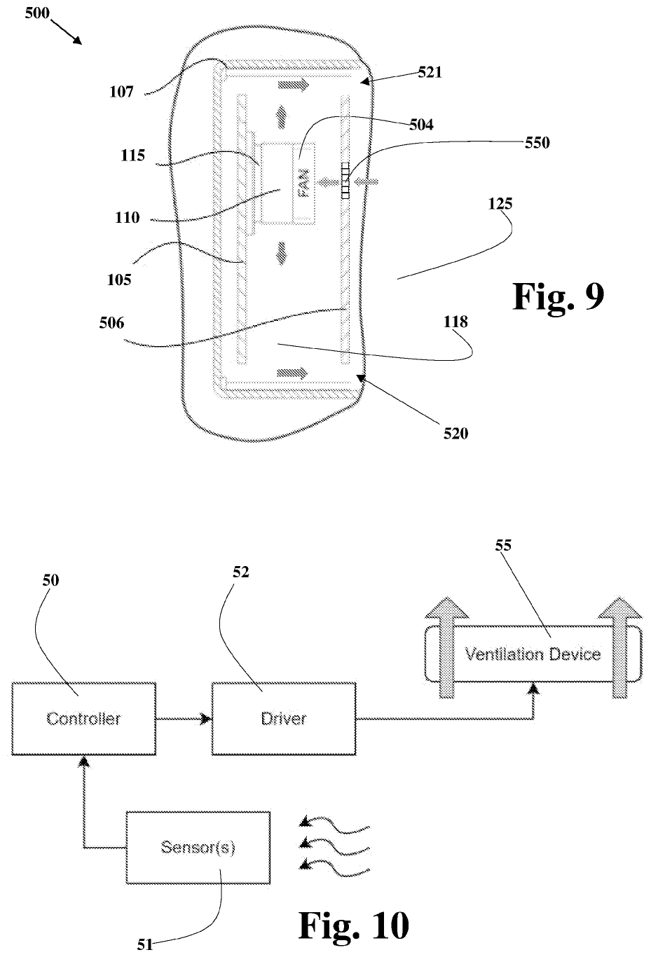

FIG. 9 shows an embodiment of a wall plate device 500 with a fan 504 blowing directly on the heat sink 110. In this embodiment, the fan 504 causes air to enter the interior of the wall plate device from a front panel opening (not shown) at the height level of the fan 504 (e.g. also passing an opening 550 in the front PCB 506). The heat sink 110 ribs are placed vertically such that the air coming from the outer environment (via the front panel opening, via the front PCB 506, via fan 506) and passing within it travels upwards and downwards, as indicated by arrows in FIG. 9. Two air flow paths are formed, one traveling upwards and exiting the device via upper opening 521 and the other air flow path traveling downwards and exiting the device via bottom opening 520. In a similar embodiment with only one PCB, the air enters the device from a middle front panel opening (preferably aligned with the fan) though the fan and directly on the heat sink, etc., mutatis mutandis.

According to another embodiment of the present invention, the present invention system comprises a ventilation device which is a Solid State Cooling Device (SSCD). According to one embodiment the SSCD is an active heat sink module (and is silent, thin and light), which comprises tiny membranes that vibrate at an ultrasonic frequency. These membranes generate a powerful flow of air that enters through the vents at one side of the SSCD and exits through tiny openings at another side (optionally perpendicular to the entrance side) as high velocity pulsating jets via an integrated spout. These pulsating jets (bursting air flows which “remove the heat”) remove heat with high efficiency with the air saturating to the same temperature of SSCD surface that engages the system electronic component.

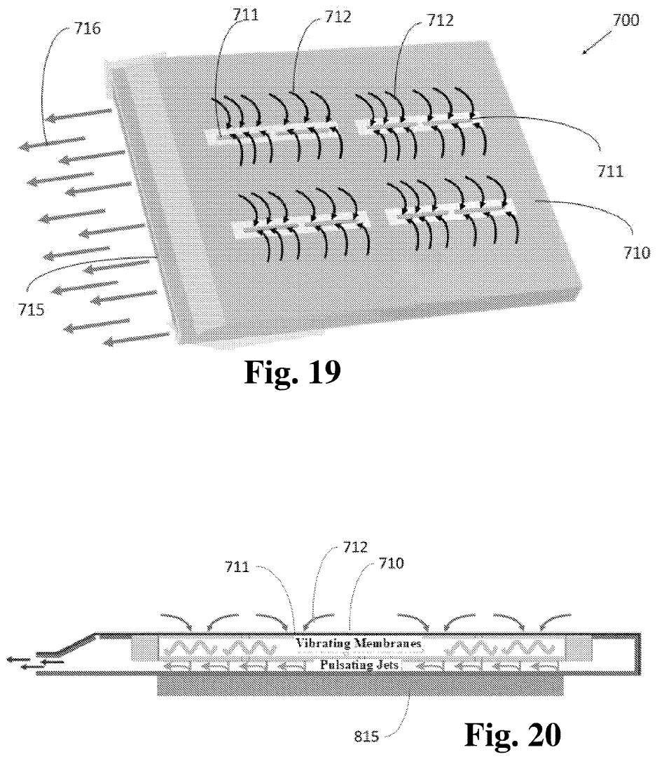

The SSCD optionally has a cuboid shape with six surfaces. One surface comprises inlet vents and another surface comprises the air exhaust opening. FIG. 19 shows an embodiment example of the SSCD 700 of the present invention (a typical SSCD) and its function of the solid-state-based exchange mechanism. The SSCD 700 comprises a rear side surface 710 comprising opening vents 711 that lead to the interior of the SSCD 700. The arrows 712 show the direction of the air flowing to the interior of the SSCD 700 via the air vents 711.

The top portion of the SSCD 700 comprises an elongated outlet opening, preferably in the form of a spout 715, where the air heated within the SSCD 700 exits. The arrows 716 show the direction of the air exiting from the interior of the SSCD 700 via the spout 715. The front surface of the SSCD is a thermally conductive surface (heat spreader-a surface which transferrers the heat). Thus, the SSCD 700 initiates an internal movement that induces air through air inlet vents 711, guides it over a thermally conductive surface (heat spreader), and expels it at high velocity through the air exhaust spout 715, carrying with it the heat absorbed from the contact surface.

The electronic component(s) of the present invention during operation, will generate heat, which will be conducted to the contact surface of the SSCD. This heat is then expelled at high speed through the SSCD outlet, thereby enhancing the efficiency of heat dissipation per unit volume area.

An example model of the SSCD may be “AirJet Pro” or “AirJet Mini” (27.5 mm×41.5×2.8) of Frore Systems.

FIG. 20 shows a cross-section of the SSCD 700. Also shown is the cross section of the electronic component 815 which is adjacent to the front side of the SSCD 700.

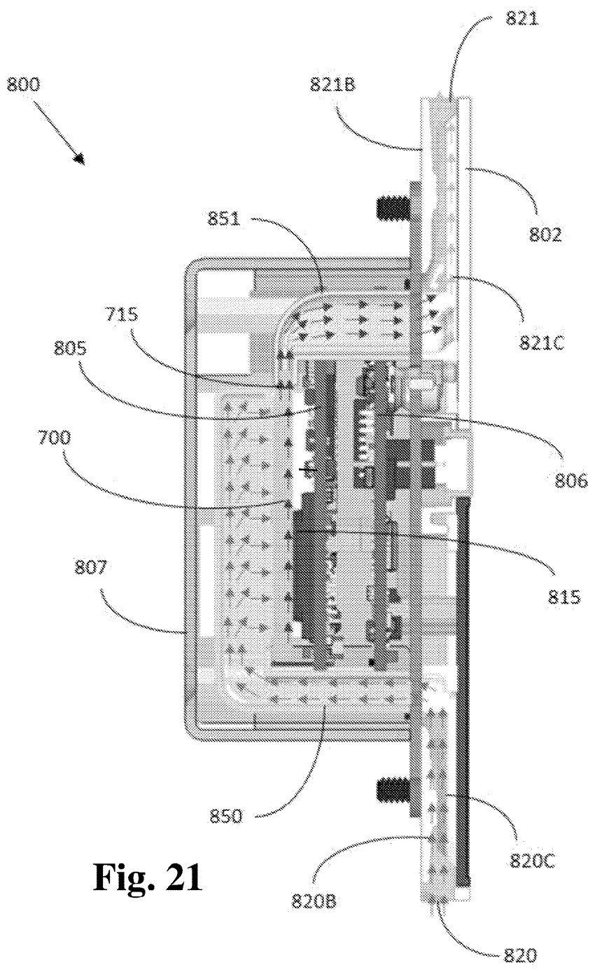

FIG. 21 shows a cross-section of a preferred embodiment of the present invention. A wall plate device 800 is shown embeddable within a wall. The wall plate device 800 comprises an inner cover 807 preferably in the form of a box. The inner cover 807 houses a vertical front PCB 806 and a vertical rear PCB 805. It should be noted that the embodiment of FIG. 21 shows two PCBs, however, other embodiments may be carried out with one PCB, with a SSCD adjacent to the front PCB, with a SSCD in between the two PCBs, mutatis mutandis. When a connector (e.g. an audio/video connector) is inserted through an insert input, it connects to the front PCB 806. The front PCB 806 is connected via a Board-to-Board (BTB) connector to the rear PCB 805. An electronic component, e.g. a (typically high power) electronic device 815 is connected to the rear side of the rear PCB 805 (e.g. by being soldered thereto), and processes the high-speed input signals that pass via the connector to the front PCB 806 and thereafter (via the connector) to the rear PCB 805 and thereafter to the electronic device 815. The electronic device 815 processes the input high-speed signals and heats up during the process. The electronic device 815 (or rear PCB 805) has an output (not shown) connected to an appropriate output within the wall infrastructure at the rear side of the rear PCB 805. A front panel cover 802 is placed vertically more forward to the front PCB 806. A housing is thereby formed having a rear box structure (cover 807) and a front panel 802 (closing the front opening of the box). The SSCD 700 is placed such that its front side engages the electronic device 815. The SSCD 700 is electrically connected to the present invention control unit (as explained herein) or to the PCB or power source.

A vertical surface 821b (typically aligned with the wall frontage) is placed from the top of the inner cover 807 opening vertically upwards. Thus, a vertical air exit channel 821c is formed between the vertical surface 821b and the rear side of the front panel cover 802 (and preferably two side surfaces not shown). The air exit channel 821c emits the heated air from the system in a vertical direction upwards. The exhaust opening 821 (which may be round) is placed at the top of the exit channel 821c.

A vertical surface 820b (typically aligned with the wall frontage) is placed from the bottom of the inner cover 807 opening vertically downwards. Thus, a vertical air entrance channel 820c is formed between the vertical surface 820b and the rear side of the front panel cover 802 (and preferably two side surfaces not shown). The air entrance channel 820c receives the cool air from the external environment 825 (room interior) in a vertical direction upwards. The suction opening 820 (which may be round) is placed at the bottom of the air entrance channel 820c.

The present invention SSCD rear side is sealably coupled to the air entrance channel and the SSCD top spout is sealably coupled to the air exit channel. According to one embodiment, the top of the air entrance channel 820c is sealably coupled to an inlet duct 850. The inlet duct 850 is a closed compartment sealably coupled to the rear side surface 710 such that air travels through the air entrance channel 820c to the inlet duct 850 and via the opening vents 711 that lead to the interior of the SSCD 700. The sealable coupling is in a manner such that the inlet duct 850 respective opening (at the end adjacent to the SSCD 700) surrounds the inlet vents 711, such that air travels from the inlet duct 850 only through the vents 711 into the SSCD 700. The bottom of the air exit channel 821c is sealably coupled to an outlet duct 851. The outlet duct 851 is a closed compartment sealably coupled to the top spout 715 such that air travels from within the interior of the SSCD 700 (after entering via vents 711) to the top spout 715 and from there to the outlet duct 851 and from there to the air exit channel 821c and out of the system. The sealable coupling between the outlet duct 851 and the SSCD outlet opening (e.g., spout 715) is in a manner such that the outlet duct 851 respective opening (at the end adjacent to the SSCD 700) surrounds the SSCD outlet opening (e.g., spout 715) such that air travels from the SSCD 700 interior to the outlet duct 851 only through the outlet opening (e.g., spout 715).

The operation of the SSCD 700 (as explained herein) propels the air stream flow of the system, causing the cool air suction in the air entrance channel 820c and emission of heated air via air exit channel 821c at high velocity. The engagement of the electronic device 815 front surface with the SSCD 700 (as a heat removal device), and constant cool air recycling causes the reducing of the device 815 heat stress (and actual cooling of the electronic device 815), enabling a better operation function thereof.

It should be noted that the wall plate device suction opening may be at the bottom or at the top of the duct and the exhaust opening at the top or bottom of the duct respectively. The SSCD is positioned accordingly, mutatis mutandis. The suction and exhaust openings may be located on both sides of the wall plate device, possibly in the right-left sides of the wall plate device, with the flow elements arranged accordingly, mutatis mutandis. In some case, for most efficiency, the suction and exhaust openings are distant from one another, e.g., each being close to the cover 807 wall surface at opposite ends.

According to an embodiment of the present invention, the ducts 850 and 851 are hollow and tubular. The ducts 850 and 851 may comprise plastic. Their sizes are adapted to be integrated with the cover 107 (similar to cover 807) and other element sized as explained herein. For example, the duct 850 may have a general length of between 40-60 mm (e.g. 47 mm length, 28 mm width, 28 mm height). For example, the duct 851 may have a general length of between 10-40 mm (e.g. 20 mm length, 31 mm width, 14 mm height). An example of the thickness of the ducts, may be in between 0.5 mm and 2 mm (e.g., 0.1 mm).

Other embodiments with the SSCD may be with openings similar to elements 120 and 121, in FIG. 5, mutatis mutandis, and will not be repeated herein for the sake of brevity and simplicity.

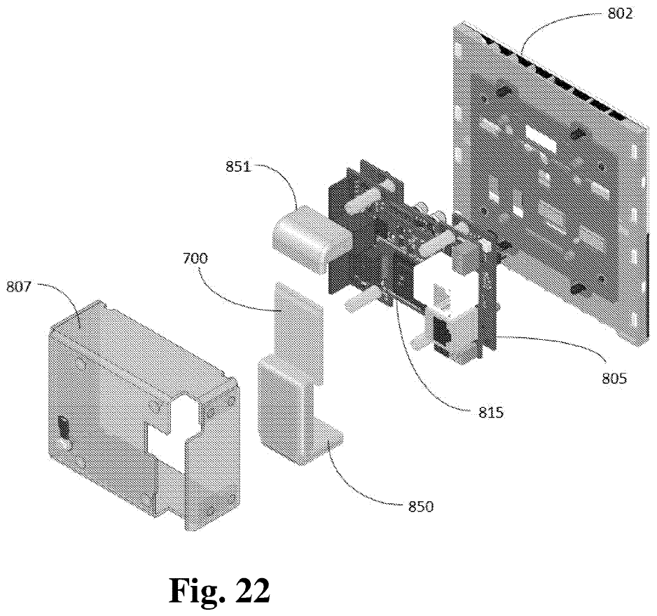

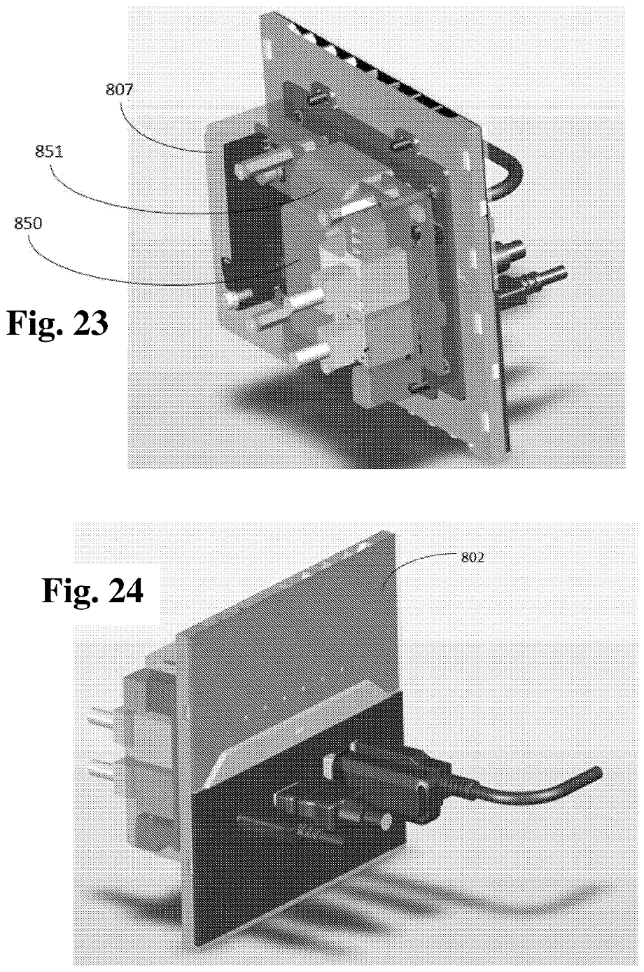

FIG. 22 shows in exploded-view diagram, some of the components of device 800. FIG. 23 shows a perspective view of the rear of device 800. The inner cover 807 is shown in transparent form. FIG. 24 shows a perspective view of the front of device 800. The inner cover 807 is shown in transparent form.

According to embodiments of the present invention, the wall plate device with the SSCD (according to all of its embodiments) also comprises the control unit (comprising a processor) and the sensor (e.g. temperature sensor) as explained herein (e.g, wherein the control unit is coupled to the sensor and coupled to the SSCD), mutatis mutandis, and will not be presented herein in detail for the sake of brevity and simplicity. The control unit may activate and control operation of the SSCD.

It should be noted that the wall plate device as explained herein according to any one of its embodiments may function with, 1 PCB device, 2 PCB devices, or more. For example, the embodiments of the wall plate device as described in FIG. 21, may work with only one PCB device (e.g. PCB device 805) and may not have a PCB device 806 (which may be considered as a specific example for reference only). For another example, the same may apply to the embodiments of FIGS. 5-9, mutatis mutandis, and will not be repeated herein for the sake of brevity and simplicity.

The present invention system may enable thermal management of the terminal units based on a combination of several disciplines, including physics, thermodynamics, airflow, electronics, software, and control.

According to an embodiment of the present invention, the present invention wall plate device comprises a control unit comprising a processor and peripherals (e.g. digital to analog). The present invention wall plate device also comprises at least one sensor (e.g. a temperature sensor, an air flow sensor) placed within the interior of the electronic circuit (or within the duct, or on the PCB itself). The control unit is connected to the sensor output. The monitoring sensor transmits to the control unit electrical signals during system operation, which reflect the measured value in analog or digital format. The control unit includes units capable of reading and processing these signals (signal conditioning), and their implementation can be in one or more integrated circuits (ICs). The signals transmitted to the control unit are compared to predefined threshold values. Once a measure read by the control unit cross-points a threshold, the control unit triggers the ventilation device (the fan or blower or SSCD). A driver may be used to enable a low power device (such as a microcontroller) to actuate a high-power device while using a power switching component (such as a transistor or a power transistor).

FIG. 10 shows an embodiment with a control unit 50 connected to at least one sensor 51 (e.g. a temperature sensor placed within the wall plate device) and to a driver 52 which sends a signal to activate a ventilation device 55 (fan or blower or SSCD). In other embodiments, the control unit 50 sends commands directly to the ventilation device 55.

According to an embodiment of the present invention, the wall plate device comprises a temperature sensor placed near or on the heat sink or near or on the electronic processing device. The control unit is connected to the temperature sensor and to the ventilation device to control the heat exchange. The heat sink may be constructed of parallel plates as explained herein or of other heat conduction mechanisms. The airflow is regulated by the control unit by activating the ventilation device according to the temperature sensor measurement, as needed (activating the ventilation device when the temperature sensor reads a temperature above a certain threshold). Possibly, a continuous operation of the ventilation device may be carried out. This control mechanism contributes to increase energy efficiency, improve the ventilation device MTBF (Mean Time Between Failures), and reduce acoustic noise. Another feasible mode of operation can be an open-loop control for the ventilation device, which operates in predefined time intervals and speeds.

The control unit may be in an on/off mode (e.g. initiating on/off commands) according to the sensor data obtained or may be in a continuous mode, initiating various commands (e.g. high ventilation, medium ventilation, low ventilation, off) according to the sensor data obtained.

For example, the ventilation device 55 may be activated on the following modes:
high ventilation mode if the sensor temperature read is above a first threshold (e.g. above 60 degrees);
medium ventilation mode if the sensor temperature read is beneath the first threshold but above a second threshold (e.g. between 50-60 degrees);
low ventilation mode if the sensor temperature read is beneath the second threshold but above a third threshold (e.g. between 45-50 degrees);
off mode if the sensor temperature read is beneath the third threshold (e.g. beneath 45 degrees).

FIG. 12 shows an example of the heat sink 110 attached and engaging the processing electronic device 115 (attached to the rear PCB 105). The heat sink 110 comprises a plurality of parallel ribs 110p engaging the processing electronic device 115. FIG. 11 shows the processing electronic device 115 without the heat sink 110.

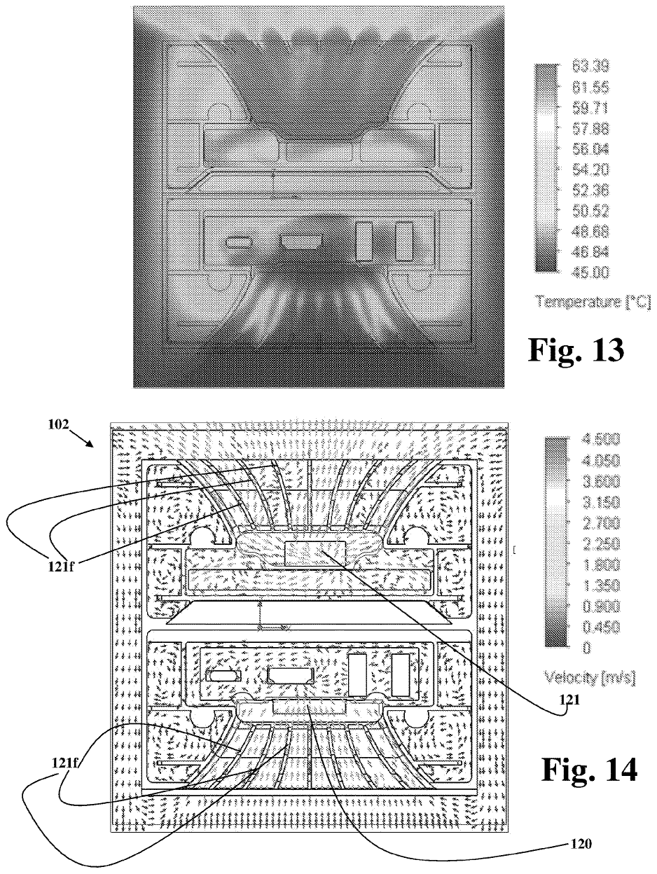

FIG. 14 shows a front view of the front panel cover 102 of FIG. 5, wherein the arrows indicate the directions and velocity of the air flow. Fin surfaces are attached to the front panel cover 102. The suction opening 120 and the exhaust opening are shown. According to this embodiment, a plurality of fins 120f are placed beneath the suction opening 120, and a plurality of fins 121f are placed above the exhaust opening. The fins 120f form a plurality of substantially parallel channels therebetween and when the air is sucked into the system via opening 120, these fins assist in preventing undesired whistling noises that may occur. The fins 121f form a plurality of substantially parallel channels therebetween and when the air is emitted from the system via opening 121, these fins assist in preventing undesired whistling noises that may occur. The fins also provide a mechanical enforcement preventing external items from forming blockages to the openings 120 and 121. FIG. 13 shows an example heat map indicating the temperature of the embodiment of FIG. 14.

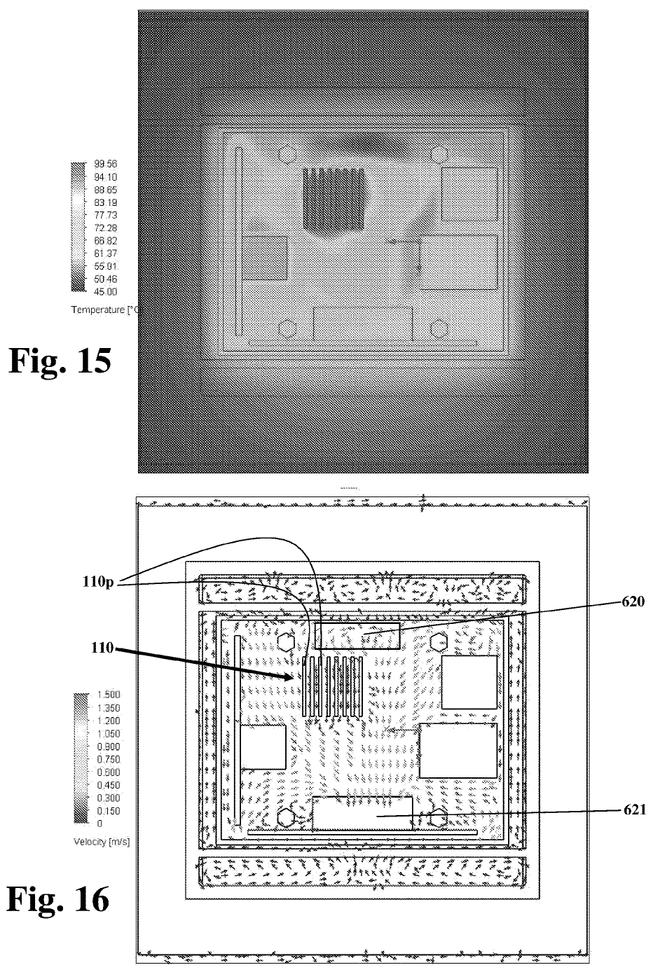

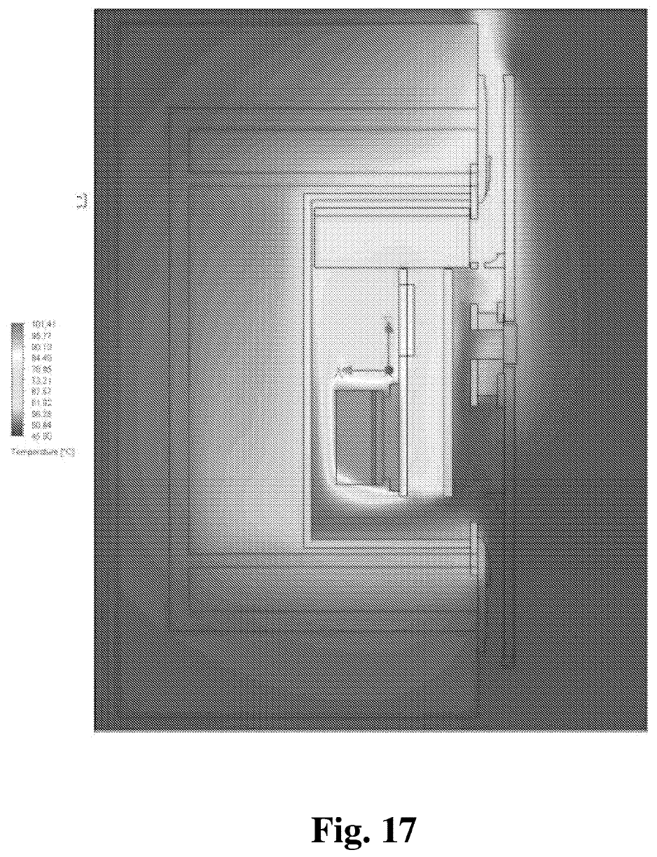

FIG. 16 shows a cross-sectional view of an interior part of a wall plate device wherein the arrows indicate the directions and velocity of the air flow (in this particular case in the figure, the air enters the device from above and exits from the bottom). The air is shown flowing into the suction opening 620 and out of the exhaust opening 621, and in between, part of the flow is between the ribs 110p of the heatsink 110. FIG. 15 shows an example heat map indicating the temperature of the embodiment of FIG. 16.

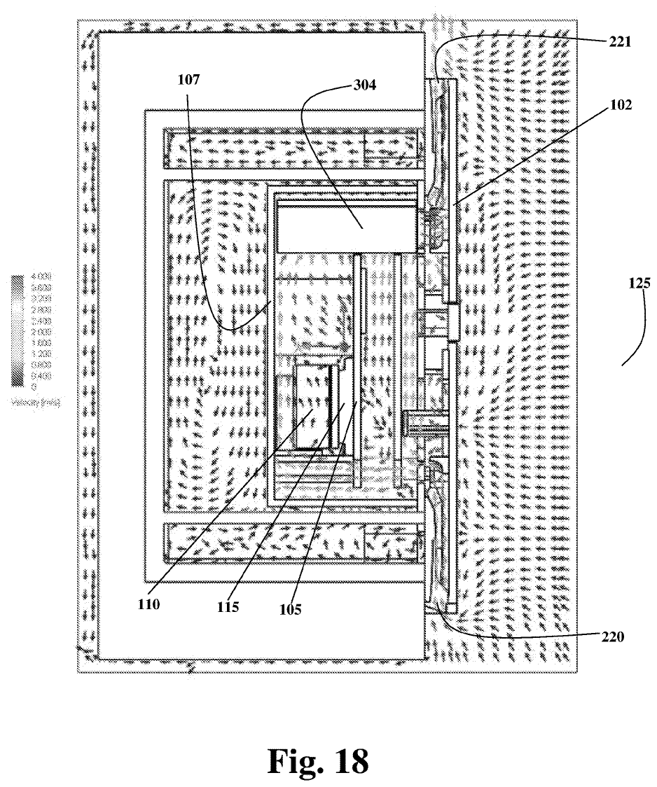

FIG. 18 shows a cross-sectional view of an interior part of a wall plate device wherein the arrows indicate the directions and velocity of the air flow. The air is shown flowing into the suction opening 220 and out of the exhaust opening 221, and in between the flow passes the heatsink 110. In this embodiment the electronic device 115 is connected to the rear side of the rear PCB 105. The suction and exhaust openings (and blower 304) are similar to the embodiment of FIG. 8. The air flow passes through the heat sink 110 and vertically upwards to the blower 304 which emits the heated air flow to the exhaust opening 221 and out of the system. FIG. 17 shows an example heat map indicating the temperature of the embodiment of FIG. 18.

The wall plate device as explained herein may be embedded within a floor, a ceiling, or other infrastructure (e.g. furniture) capable of imbedding it. Therefore, the directions, definitions of the components relationship (i.e. being horizontal/vertical front/rear, etc.), will be changed accordingly, mutatis mutandis, as would be known to a person skilled in the art.

A model example of fan 104 is BFB0305HHA-C of Delta Group. A model example of the blower 304 is Blower Delta BSB0205HP-00 of Delta Group.

The length of the inner cover 107 that houses most of the components of the wall plate device is usually between 100 and 80 mm. Its width is usually between 36 and 26 mm. Its height is usually between 78 and 60 mm.

The length of the openings 120 and 121 is usually between 25 and 16 mm. Its widths are usually between 10 and 4 mm. The diameters of the openings 220 and 221 are usually between 3.5 mm and 4 mm.

The length of the heat sink 110 is usually between 24 and 18 mm. Its width is usually between 8 and 14 mm. Its height is usually between 24 and 18 mm. The thickness of each plate 110p is usually between 0.5 and 1.5 mm (their pitch may preferably be 2.24).

The front panel cover 102 length is usually between 130 and 100 mm. Its width is usually between 130 and 100 mm. Its thickness is usually between 10 and 5 mm.

The front panel cover 102 preferably comprises material from the group consisting of metal and plastic.

The heat sink 110 preferably comprises thermally conductive material.

The inner cover 107 preferably comprises material from the group consisting of metal and plastic.

The vertical air entrance channel 220c and the vertical air exit channel 221c, each have a length usually between 45 and 55 mm. Their width is usually between 2 and 5 mm. Their height is usually between 30 and 50 mm.

### EXAMPLE

Ambient temperature that was measured inside the interior of a wall plate device, was around 65 degrees Celsius at room temperature of 21 C. Ambient inside the device is usually around 96 degrees Celsius, at room temperature of 50 degrees Celsius.

A wall plate device of the present invention was used. A variable power supply was provided. A 9 W power resistor emulating the electronic circuit, a blower (a Sunon blower) and a temperature probe were placed inside an inner cover/housing/encloser. Measurements were taken with variable fan voltage (0V, 2V, 3.3V & 5V).

### RESULTS

The results can be seen the table below:

| | | | Fan | Encloser | Room | | |
|---|---|---|---|---|---|---|---|
| Voltage | Current | Power | Voltage | Temp. | Temp. | | |
| (V) | (A) | (W) | (V) | ( ® C.) | ( ® C.) | Start | End |
| 0 | 0 | 0.00 | 0 | 20.8 | | | |
| 1.8 | 0.63 | 1.13 | 0 | 28.5 | | | |
| 4.3 | 1.5 | 6.45 | 0 | 58.5 | | 09:12 | 09:53 |
| 5 | 1.7 | 8.50 | 0 | 65.5 | 23.4 | 10:00 | |
| 5 | 1.7 | 8.50 | 2 | 51.2 | 22.3 | 11:08 | 11:51 |
| 5 | 1.7 | 8.50 | 3.3 | 46.2 | 22.7 | 11:51 | 12:20 |
| 5 | 1.7 | 8.50 | 5 | 41.2 | 22.9 | 12:21 | 13:22 |

### CONCLUSION

As can be seen from the results, using a blower can decrease dramatically the ambient temperature inside an encloser (up to 24®C).

The present invention relates to a method for removing heat from a wall plate device (e.g. 100, 200, 300, 400, 500), comprising passing an air flow through a duct in said wall plate device (e.g. by the ventilation device as explained herein) comprising: passing an air flow through a suction opening (120, 220) at the frontage of said wall plate device (e.g. front panel 102) to the interior of said wall plate device (e.g. 118);
directing said air flow such that a portion thereof passes near an electronic component (e.g. 115; or optionally, near or through a heat sink 110 that engages said electronic component) directing said air flow through an exhaust opening (121, 221) at the frontage of said wall plate device out of said wall plate device.

Preferably, providing the wall plate device comprises a ventilation device (e.g. 104, 304), a temperature sensor (e.g. sensor 51) and a control unit (e.g. control unit 50) coupled to said ventilation device and to said temperature sensor;
the method further comprises determining a temperature from said temperature sensor;
setting the ventilation device to an activation mode depending on the temperature determined (e.g. on or off; high, medium, low, or off activation modes, as explained herein).

The present invention method also comprises the method/function steps as explained herein in relation to the present invention system/device.

The present invention relates to a method for removing heat from a wall plate device (e.g. 800 comprising passing an air flow through a duct (820c-850-700-851-821c) in said wall plate device comprising:
passing an air flow through a suction opening at the frontage of said wall plate device to the interior of an SSCD;
directing said air flow from the SSCD interior an exhaust opening at the frontage of said wall plate device out of said wall plate device. The method may comprise all of the steps as explained herein regarding the system device 800.

In some embodiments, the method further comprises:
providing the wall plate device comprises a temperature sensor and a control unit coupled to the SSCD and to said temperature sensor;
determining a temperature from said temperature sensor;
setting the SSCD to an activation mode depending on the temperature determined.

While some of the embodiments of the invention have been described by way of illustration, it will be apparent that the invention can be carried into practice with many modifications, variations and adaptations, and with the use of numerous equivalents or alternative solutions that are within the scope of a person skilled in the art, without departing from the spirit of the invention, or the scope of the claims.

1. A wall plate device embeddable within a wall or other fixed medium, comprising:
a housing comprising a rear cover optionally in the work of a box and a front panel;
a suction opening placed at the frontage of said device;
an exhaust opening placed at the frontage of said device;
at least one PCB placed within said rear cover with input and output connectors;
at least one electronic component connected to said PCB;
a ventilation device configured to propel an air flow from said suction opening and to said exhaust opening, part of which passes adjacent to said electronic component.

2. The wall plate device according to claim 1, wherein the ventilation device and electronic component are placed within a duct; and wherein the air flow passes along said duct.

3. The wall plate device according to claim 2, wherein the ventilation device is placed between the electronic component and the suction opening along the duct.

4. The wall plate device according to claim 3, wherein the ventilation device is a fan.

5. The wall plate device according to claim 1, wherein the suction opening and the exhaust opening are openings in the front panel.

6. The wall plate device according to claim 5, further comprising a plurality of fin surfaces attached to the front panel;
wherein a plurality of said fin surfaces are placed near the suction opening; and
wherein a plurality of said fin surfaces are placed near the exhaust opening.

7. The wall plate device according to claim 2, further comprising a vertical entrance channel and a vertical exit channel;
wherein said vertical entrance channel is coupled at one end to the suction opening and at the other end to the interior of the duct; and
wherein said vertical exit channel is coupled at one end to the exhaust opening and at the other end to the interior of the duct.

8. The wall plate device according to claim 1, wherein said device further comprises a control unit comprising a processor, and a sensor;
wherein the control unit is coupled to said sensor and coupled to said ventilation device.

9. The wall place device according to claim 8, wherein the sensor is a temperature sensor.

10. The wall plate device according to claim 1, wherein the ventilation device is a blower configured to receive an air flow from an input from one direction and emit an air flow from an output at another direction;
wherein said output faces the exhaust opening.

11. The wall plate device according to claim 7, wherein the ventilation device is a blower configured to receive an air flow from an input from one direction and emit an air flow from an output at another direction;
wherein said output faces one end of the exit channel.

12. The wall plate device according to claim 1, comprising a front PCB and a rear PCB placed within said rear cover, each having input and output connectors;
wherein the ventilation device and electronic component(s) are placed between the front PCB and rear PCB.

13. The wall place device according to claim 12, wherein the front PCB comprises an audio or video input connector; and
wherein the rear PCB is connected to said front PCB.

14. The wall plate device according to claim 12, wherein the front PCB comprises an audio or video input connector; and
wherein the rear PCB comprises an audio or video output connector.

15. The wall place device according to claim 1, further comprising a heat sink that engages the electronic component;
wherein part of the air flow passes adjacent to said heat sink.

16. A wall plate device embeddable within a wall or other fixed medium, comprising:
a housing comprising a rear cover optionally in the form of a box and a front panel;
an upper opening placed at the frontage of said device;
a bottom opening placed at the frontage of said device;
a middle opening placed at the frontage of said device and between said upper opening and bottom opening;
at least one PCB placed within said rear cover with input and output connectors;
at least one electronic component connected to said PCB;
a heat sink engaging said electronic component;
a fan facing the heat sink and configured to blow air directly on said heat sink;
wherein said fan is configured to propel:
a. a first air flow via said middle opening into said device, and on to the heat sink
b. a second air flow from said heat sink to the upper opening;
c. a third air flow from said heat sink to the bottom opening.

17. A method for removing heat from a wall plate device, comprising passing an air flow through a duct in said wall plate device comprising:
passing an air flow through a suction opening at the frontage of said wall plate device to the interior of said wall plate device;
directing said air flow such that a portion thereof passes near an electronic component;
directing said air flow through an exhaust opening at the frontage of said wall plate device out of said wall plate device.

18. The method according to claim 17,
providing the wall plate device comprises a ventilation device, a temperature sensor and a control unit coupled to said ventilation device and to said temperature sensor;
determining a temperature from said temperature sensor;
setting the ventilation device to an activation mode depending on the temperature determined.

19. A wall plate device embeddable within a wall or other fixed medium, comprising:
a housing comprising a rear cover, optionally in the form of a box and a front panel;
a suction opening placed at the frontage of said device;
an exhaust opening placed at the frontage of said device;
at least one PCB placed within said rear cover with input and output connectors;
at least one electronic component connected to said PCB;
an SSCD placed adjacent to said electronic component;
wherein said SSCD is configured to propel an air flow from said suction opening via said SSCD and out through said exhaust opening.

20. The wall plate device according to claim 19, wherein the SSCD comprises inlet vents and an outlet opening.

21. The wall plate device according to claim 20, further comprising a vertical entrance channel and a vertical exit channel;
wherein said vertical entrance channel is coupled at one end to the suction opening and sealably coupled at the other end to an inlet duct;
wherein said vertical exit channel is coupled at one end to the exhaust opening and sealably coupled at the other end to an outlet duct;
wherein the inlet duct is sealably coupled to the SSCD such that air is configured to pass from the inlet duct into the SSCD interior only through the inlet vents; and
wherein the outlet duct is sealably coupled to the SSCD such that air is configured to pass from the SSCD interior to the outlet duct only through the SSCD outlet opening.

22. The wall plate device according to claim 20, wherein the SSCD outlet opening is in the form of a spout.

23. The wall plate device according to claim 19, wherein said device further comprises a control unit comprising a processor, and a sensor;
wherein the control unit is coupled to said sensor and coupled to said SSCD.

24. The wall plate device according to claim 23, wherein the sensor is a temperature sensor.

25. The wall plate device according to claim 19, comprising a front PCB and a rear PCB placed within said rear cover, each having input and output connectors;
wherein the electronic component(s) is attached to the rear side of the rear PCB and the SSCD is placed adjacent to the rear side of the electronic component.

26. A method for removing heat from a wall plate device, comprising passing an air flow through a duct in said wall plate device comprising:
passing an air flow through a suction opening at the frontage of said wall plate device to the interior of an SSCD;
directing said air flow from the SSCD interior an exhaust opening at the frontage of said wall plate device out of said wall plate device.

27. The method according to claim 26, further comprising:
providing the wall plate device comprises a temperature sensor and a control unit coupled to the SSCD and to said temperature sensor;
determining a temperature from said temperature sensor;
setting the SSCD to an activation mode depending on the temperature determined.
